(19) United States
(12) Patent Application Publication
(10) Pub. No.: US 2024/0203836 A1
(43) Pub. Date: Jun. 20, 2024

(54) SEMICONDUCTOR PACKAGE INCLUDING A HIGH VOLTAGE SEMICONDUCTOR DIE AND A GATE DRIVER SEMICONDUCTOR DIE, AND METHOD OF PRODUCING THE SEMICONDUCTOR PACKAGE

(71) Applicant: Infineon Technologies Austria AG, Villach (AT)

(72) Inventors: Hugh Richard, Gravesend (GB); Mark Pavier, Felbridge (GB)

(21) Appl. No.: 18/083,763

(22) Filed: Dec. 19, 2022

(51) Int. Cl. H01L 23/495; H01L 21/78; H01L 23/00; H01L 23/15; H01L 23/31; H01L 25/16

(52) U.S. Cl. CPC H01L 23/49513; H01L 21/78; H01L 23/15; H01L 23/3121; H01L 24/29; H01L 24/32; H01L 25/165; H01L 2224/2919; H01L 2224/32225

(57) ABSTRACT

A semiconductor package includes a substrate, a high voltage semiconductor die attached to an electrically conductive part of the substrate, and a gate driver semiconductor die attached, by an electrically insulative die attach material, to the electrically conductive part of the substrate or to a side of the high voltage semiconductor die that faces away from the substrate. The gate driver semiconductor die includes a semiconductor body and a polymer material covering a backside of the semiconductor body. The polymer material is interposed between the semiconductor body and the die attach material such that the semiconductor body is electrically insulated from the substrate or the side of the high voltage semiconductor die that faces away from the substrate by an insulator stack that includes both the polymer material and the die attach material. A method of producing the semiconductor package also is described.

### BACKGROUND

High voltage discrete or microcontroller modules require a gate driver. If the gate driver and high voltage switch devices are placed on the same lead frame, the gate driver must be isolated from the package lead frame. The gate driver is typically isolated by using a separate paddle on the lead frame or by using an interposer such as ceramic, glass or polymer between the gate driver and the lead frame. In the case of a separate paddle for providing the isolation, the spacing between pads which are exposed on the outside of the package must be large enough to accommodate the difference in voltage which increases the package size and adds to the overall product cost. In the case of an interposer for providing the isolation, the interposer represents a significant cost adder due to the additional material cost for the interposer and process step for placing the interposer.

Accordingly, there is a need for an improved technique for isolating gate drivers from high voltage switch devices in high voltage discrete or microcontroller modules.

### SUMMARY

According to an embodiment of a semiconductor package, the semiconductor package comprises: a substrate; a high voltage semiconductor die attached to an electrically conductive part of the substrate; and a gate driver semiconductor die attached, by an electrically insulative die attach material, to the electrically conductive part of the substrate or to a side of the high voltage semiconductor die that faces away from the substrate, wherein the gate driver semiconductor die comprises a semiconductor body and a polymer material covering a backside of the semiconductor body, wherein the polymer material is interposed between the semiconductor body and the die attach material such that the semiconductor body is electrically insulated from the substrate or the side of the high voltage semiconductor die that faces away from the substrate by an insulator stack that comprises both the polymer material and the die attach material.

According to an embodiment of a method of producing a plurality of semiconductor packages, the method comprises: forming a gate driver circuit at a plurality of die locations in a semiconductor wafer; thinning a backside of the semiconductor wafer; covering the thinned backside of the semiconductor wafer with a polymer material; singulating the semiconductor wafer with the polymer material into a plurality of gate driver semiconductor dies; and for each gate driver semiconductor die: attaching a high voltage semiconductor die to an electrically conductive part of a substrate; and attaching, by an electrically insulative die attach material, the gate driver semiconductor die to the electrically conductive part of the substrate or to a side of the high voltage semiconductor die that faces away from the substrate, wherein the polymer material is interposed between a semiconductor body of the gate driver semiconductor die and the die attach material such that the semiconductor body is electrically insulated from the substrate or the side of the high voltage semiconductor die that faces away from the substrate by an insulator stack that comprises both the polymer material and the die attach material.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A through 1F illustrate cross-sectional views of part of a semiconductor wafer during different stages of a method of producing semiconductor packages.

FIG. 2 illustrates a cross-sectional view of an embodiment of a semiconductor package that includes at least one of the gate driver semiconductor dies produced from the semiconductor wafer.

FIG. 3 illustrates a cross-sectional view of another embodiment of a semiconductor package that includes at least one of the gate driver semiconductor dies produced from the semiconductor wafer.

FIG. 4 illustrates a cross-sectional view of another embodiment of a semiconductor package that includes at least one of the gate driver semiconductor dies produced from the semiconductor wafer.

FIG. 5 illustrates a cross-sectional view of another embodiment of a semiconductor package that includes at least one of the gate driver semiconductor dies produced from the semiconductor wafer.

### DETAILED DESCRIPTION

The embodiments described provide a polymer isolation material applied to the backside of a gate driver semiconductor die (chip) as part of wafer processing. The gate driver semiconductor die with the backside polymer isolation material can be singulated from a wafer and die bonded using an electrically insulative material without the need for an interposer. Breakdown due to voids in the electrically insulative die attach material is avoided by applying the polymer isolation material to the backside of the gate driver semiconductor die, which provides the primary isolation.

Described next, with reference to the figures, are embodiments of producing the backside-isolated gate driver semiconductor dies and semiconductor packages that include the gate driver semiconductor dies.

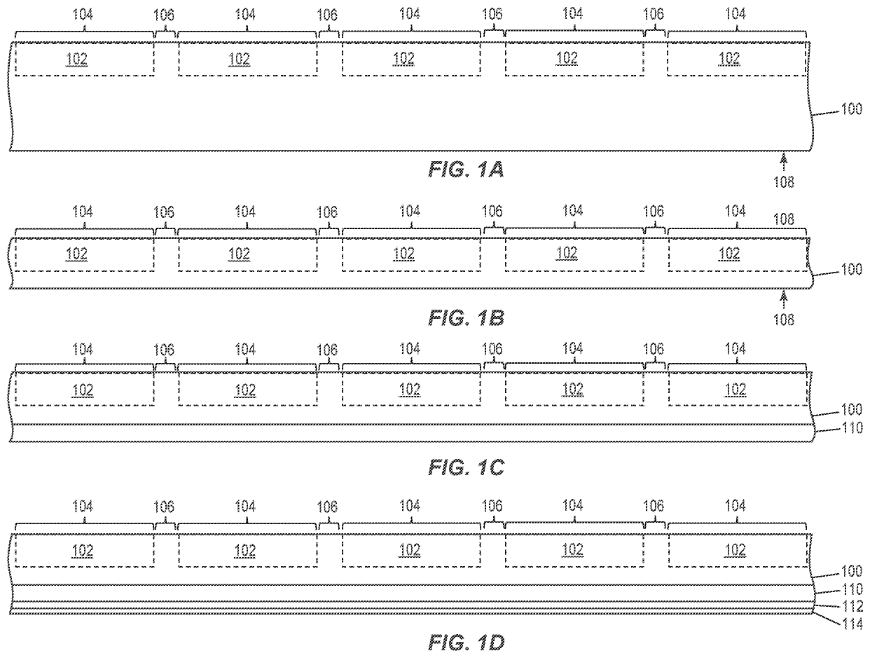

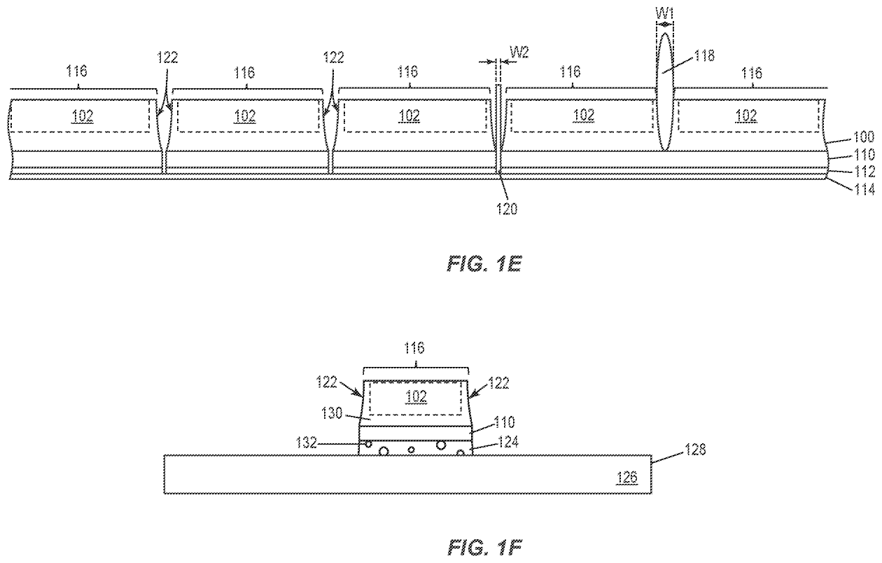

FIGS. 1A through 1F illustrate cross-sectional views of part of a semiconductor wafer 100 during different stages of a method of producing semiconductor packages. The semiconductor wafer 100 may be any type of semiconductor wafer suitable for producing high voltage semiconductor dies (chips), where the term ‘high voltage semiconductor die’ as used herein means any type of semiconductor die having a rated/breakdown voltage of at least 60V. For example, the semiconductor wafer 100 may be a Si (silicon) wafer, an SOI (silicon-on-insulator) wafer, a SiC (silicon carbide) wafer, a GaN (gallium nitride) wafer, a GaAs (gallium arsenide) wafer, etc.

FIG. 1A shows the semiconductor wafer 100 after a gate driver circuit 102 is formed at a plurality of die locations 104 in the semiconductor wafer 100. Each gate driver circuit 102 is represented by a dashed rectangle in FIGS. 1A through 1F, and may have a differential input, one or more driving strength options, an active Miller clamp, a bootstrap voltage clamp, a range of output current options, e.g., from 0.1 A up to 10 A or higher, fault protection, shutdown protection, over current protection, etc. Each gate driver circuit 102 may be designed to drive any type of power semiconductor switch device such as a power MOSFET (metal-oxide-semiconductor field-effect transistor), IGBT (insulated gate bipolar transistor), JFET (junction FET), Fin-FET, HEMT (high-electron mobility transistor), etc. or any type of high voltage IC such as a microcontroller. The die locations 104 are separated from one another by dicing streets 106 which are regions of the semiconductor wafer 100 that delimit die locations and are subsequently diced, e.g., by sawing, laser cutting, etc. to produce individual gate driver semiconductor dies.

FIG. 1B shows the semiconductor wafer 100 after thinning the backside 108 of the semiconductor wafer 100. The wafer backside 108 may be thinned by grinding, etching, CMP (chemical-mechanical polishing), etc.

FIG. 1C shows the semiconductor wafer 100 after covering the thinned backside 108 of the semiconductor wafer 100 with a polymer material 110 such as an epoxy or a polyimide, for example. In one embodiment, the polymer material 110 is a thermosetting polymer film laminated to the thinned backside 108 of the semiconductor wafer 100. The thermosetting polymer film may be laminated to the thinned wafer backside 108 using standard wafer lamination equipment and cured, e.g., for 120 minutes at 130° C. The polymer material 110 may have a thickness of at least 25 μm (microns). For example, the thickness of the polymer material 110 may be in a range of 25 μm to 50 μm. The polymer material 110 may have a dielectric strength greater than 25 kV/mm.

FIG. 1D shows the semiconductor wafer 100 after a die attach material 112 is applied to the polymer material 110 and a dicing film 114 is applied to the die attach material 112. The die attach material 112 may be a polymer film or an epoxy adhesive and may have a thickness in a range of 20 μm to 30 μm. The die attach material 112 may be applied before or after wafer dicing. In one embodiment, the polymer material 110 applied to the thinned backside 108 of the semiconductor wafer 100 comprises a different material than the die attach material 112. For example, the polymer material 110 may be an epoxy or a polyimide and the die attach material 112 may be a dicing tape film that comprises a polymer such as polyolefin, an acrylic resin, an epoxy resin, a polyester resin, or any combination thereof. The polymer material 110 may contain inorganic fillers such as silica to increase strength and isolation rating.

FIG. 1E shows the semiconductor wafer 100 during wafer singulation. The semiconductor wafer 100 is singulated into a plurality of gate driver semiconductor dies 116, with the polymer material 110 already applied to the wafer backside 108.

In one embodiment, singulation of the semiconductor wafer 100 includes attaching the thinned backside 108 of the semiconductor wafer 100 with the polymer material 110 to the dicing film 114 by the die attach material 112. The semiconductor wafer 110 is then cut through along the dicing streets 106 which delimit the die locations 104 using a first blade 118 having a first width W1. Both the polymer material 110 and the die attach material 112 are then cut through along the dicing streets 106 using a second blade 120 having a second width W2 that is less than the first width W1.

The first dicing blade 118 may be tapered, e.g., such that the cutting using the first blade 118 tapers inward an edge 122 of each gate driver semiconductor die 116. According to this embodiment, the tapered edge 122 of the gate driver semiconductor dies 116 creates a step between the die semiconductor material and the polymer material 110 applied to the backside 108 of the dies 116. The tapered edge 122 increases tracking distance and reduces a risk of metal fragments in the dicing streets 106 from being carried to the edge 122 of the gate driver semiconductor dies 116 which would otherwise create a leakage path.

Other techniques such as laser cutting may be used to singulate the semiconductor wafer 100 into the individual gate driver semiconductor dies 116. As explained above, the die attach material 112 may be applied to the polymer material 110 before or after singulation of the semiconductor wafer 100. The gate driver semiconductor dies 116 may be electrically tested before and/or after the wafer singulation process.

FIG. 1F shows an individual gate driver semiconductor die 116 after being attached, by an electrically insulative die attach material 124, to an electrically conductive part 126 of a substrate 128. The polymer material 110 previously applied to the backside of the gate driver semiconductor die 116 is interposed between the semiconductor body 130 of the gate driver semiconductor die 116 and the electrically insulative die attach material 124, such that the semiconductor body 130 is electrically insulated from the substrate 128 by an insulator stack that includes both the polymer material 110 and the die attach material 124. Accordingly, breakdown due to voids 132 in the electrically insulative die attach material 124 is avoided by the gate driver backside polymer material 110 which provides the primary isolation.

In one embodiment, the die attach material 112 used during wafer singulation remains on the polymer material 110 of the individual gate driver semiconductor dies 116 after the singulation process and forms the electrically insulative die attach material 124. Accordingly, the electrically insulative die attach material 124 may be a die attach film or an epoxy adhesive used during the wafer singulation process, e.g., as shown in FIG. 1E.

In another embodiment, the die attach material 112 used during the wafer singulation process is removed after the wafer singulation process and a different material is used as the electrically insulative die attach material 124 that attaches the gate driver semiconductor die 116 to the electrically conductive part 126 of the substrate 128. In either case, the polymer material 110 applied to the backside of the gate driver semiconductor die 116 may be thicker than the electrically insulative die attach material 124. For example, the polymer material 110 may have a thickness in a range of 25 μm to 50 μm and the electrically insulative die attach material 124 may have a thickness in a range of 20 μm to 30 μm.

The substrate 128 to which the gate driver semiconductor die 116 is attached may be a die paddle of an electrically conductive lead frame such as a Cu (copper) lead frame, for example. According to this embodiment, the entire substrate 128 is electrically conductive. In another embodiment, the substrate 128 includes a ceramic body and the electrically conductive part 126 of the substrate 128 is a segment of a patterned metallization formed on the ceramic body. In another embodiment, the substrate 128 is a laminate and the electrically conductive part 126 of the substrate 128 is a segment of a patterned metallization formed on the laminate.

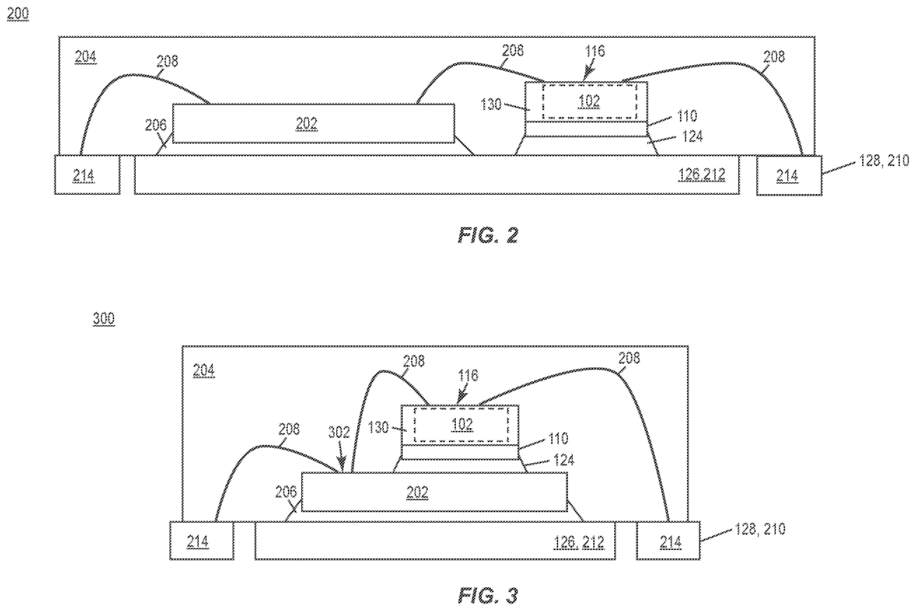

FIG. 2 illustrates a cross-sectional view of an embodiment of a semiconductor package 200 that includes at least one of the gate driver semiconductor dies 116 with the backside polymer material 110. The gate driver semiconductor die 116 is attached, by the electrically insulative die attach material 124, to the electrically conductive part 126 of the substrate 128 and a high voltage semiconductor die 202 also is attached to the electrically conductive part 126 of the substrate 128. The high voltage semiconductor die 202 has a rated/breakdown voltage of at least 60V and may be a microcontroller die for a high voltage transistor, a discrete high voltage transistor die such as a discrete Si or SiC power MOSFET die, a discrete Si or SIC JFET die, a discrete Si IGBT die, a discrete GaN HEMT die, etc. A mold compound 204 may encapsulate the high voltage semiconductor die 202 and the gate driver semiconductor die 116.

As explained above, the gate driver semiconductor die 116 has a semiconductor body 130 and a polymer material 110 covering the backside of the semiconductor body 130. The polymer material 130 is interposed between the semiconductor body 130 and the electrically insulative die attach material 124, such that the semiconductor body 130 is electrically insulated from the electrically conductive part 126 of the substrate 128 by an insulator stack that includes both the polymer material 110 and the electrically insulative die attach material 124. In one embodiment, the insulator stack has a breakdown voltage greater than 3 kV.

The high voltage semiconductor die 202 is attached to the electrically conductive part 126 of the substrate 128 by a die attach material 206. The die attach material 206 may be the same or a different material as the electrically insulative die attach material 124 that attaches the gate driver semiconductor die 116 to the electrically conductive part 126 of the substrate 128. For example, if the high voltage semiconductor die 202 is a lateral device with no electrical connection to the substrate 128, the die attach materials 124, 206 may comprise the same electrically insulative material.

If, however, the high voltage semiconductor die 202 is a vertical device with an electrical connection to the electrically conductive part 126 of the substrate 128, the die attach material 206 that attaches the high voltage semiconductor die 202 to the substrate 128 is electrically conductive. For example, the die attach material 206 that attaches the high voltage semiconductor die 202 to the substrate 128 may be solder, an electrically conductive adhesive, a sintered material, etc. whereas the die attach material 124 that attaches the gate driver semiconductor die 116 to the substrate 128 may be an electrically insulative die attach film, epoxy adhesive, etc. In either case, electrical connections 208 such as bond wire connections, ribbon connections, metal clip connections, etc. may be formed between the topside of the respective semiconductor dies 116, 202 and the substrate 108 and/or between the dies 116, 202.

In FIG. 2, the substrate 128 is a lead frame 210 and both the gate driver semiconductor die 116 and the high voltage semiconductor die 202 are attached to a die paddle 212 of the lead frame 210. The lead frame 210 also includes leads 214 to accommodate the electrical connections 208 to the respective semiconductor dies 116, 202. The leads 214 may be surface mount leads, through hole leads, etc. In each case, the semiconductor body 130 of the gate driver semiconductor die 116 is electrically insulated from the die paddle 212 of the lead frame 210 by both the backside polymer material 110 and the electrically insulative die attach material 124 used to attach the gate driver semiconductor die 116 to the die paddle 212.

FIG. 3 illustrates a cross-sectional view of another embodiment of a semiconductor package 300 that includes at least one of the gate driver semiconductor dies 116 with the backside polymer material 110. The semiconductor package 300 in FIG. 3 is similar to the semiconductor package 200 in FIG. 2. However, in FIG. 3, the gate driver semiconductor die 116 is attached, by the electrically insulative die attach material 124, to the side 302 of the high voltage semiconductor die 202 that faces away from the die paddle 212 of the lead frame 210. The semiconductor body 130 of the gate driver semiconductor die 116 is electrically insulated from the high voltage semiconductor die 202 by both the polymer material 110 applied to the backside of the gate driver semiconductor die 116 and the electrically insulative die attach material 124 used to attach the gate driver semiconductor die 116 to the high voltage semiconductor die 202.

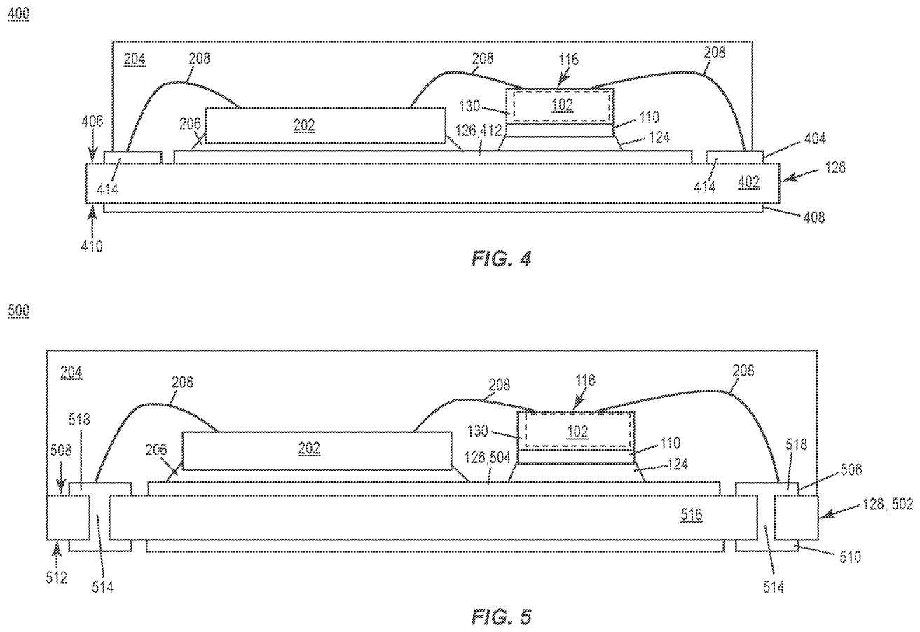

FIG. 4 illustrates a cross-sectional view of another embodiment of a semiconductor package 400 that includes at least one of the gate driver semiconductor dies 116 with the backside polymer material 110. The semiconductor package 400 in FIG. 4 is similar to the semiconductor package 200 in FIG. 2. However, in FIG. 4, the substrate 128 includes a ceramic body 402 with a patterned metallization 404 formed on the topside 406 of the ceramic body 402. A patterned or unpatterned metallization 408 may be formed on the backside 410 of the ceramic body 402. The substrate 128 in FIG. 4 may be a DCB (direct copper bonded) substrate, a DAB (direct aluminum bonded) substrate, an AMB (active metal brazed) substrate, an IMS (insulated metal substrate), etc.

In FIG. 4, the electrically conductive part 126 of the substrate 128 is a segment 412 of the patterned metallization 404 formed on the topside 406 of the ceramic body 402. Both the gate driver semiconductor die 116 and the high voltage semiconductor die 202 are attached to the segment 412 of the topside patterned metallization 412. The semiconductor body 130 of the gate driver semiconductor die 116 is electrically insulated from the segment 412 of the topside patterned metallization 412 by both the polymer material 110 applied to the backside of the gate driver semiconductor die 116 and the electrically insulative die attach material 124 used to attach the gate driver semiconductor die 116 to the topside patterned metallization 412. The topside patterned metallization 412 may include additional segments 414 to accommodate the electrical connections 208 to the respective semiconductor dies 116, 202.

FIG. 5 illustrates a cross-sectional view of another embodiment of a semiconductor package 500 that includes at least one of the gate driver semiconductor dies 116 with the backside polymer material 110. The semiconductor package 500 in FIG. 5 is similar to the semiconductor package 400 in FIG. 4. However, in FIG. 5, the substrate 128 is a laminate 502 such as a PCB (printed circuit board). The electrically conductive part 126 of the substrate 128 is a segment 504 of a patterned metallization 506 formed on the topside 508 of the laminate 502. A patterned metallization 510 may be formed on the backside 512 of the laminate 502. The patterned metallizations 506, 510 may be electrically interconnected by vias 514 that extend through an electrically insulative body 516 of the laminate 502. The laminate 502 is depicted as a single-layer PCB in FIG. 5 but instead may be a multi-layer PCB.

In either case, both the gate driver semiconductor die 116 and the high voltage semiconductor die 202 are attached to the same segment 504 of the topside patterned metallization 506 in FIG. 5. The semiconductor body 130 of the gate driver semiconductor die 116 is electrically insulated from the segment 504 of the topside patterned metallization 506 by both the polymer material 110 applied to the backside of the gate driver semiconductor die 116 and the electrically insulative die attach material 124 used to attach the gate driver semiconductor die 116 to the topside patterned metallization 506. The topside patterned metallization 506 of the laminate 502 may include additional segments 518 to accommodate the electrical connections 208 to the respective semiconductor dies 116, 202.

Although the present disclosure is not so limited, the following numbered examples demonstrate one or more aspects of the disclosure.

Example 1. A semiconductor package, comprising: a substrate; a high voltage semiconductor die attached to an electrically conductive part of the substrate; and a gate driver semiconductor die attached, by an electrically insulative die attach material, to the electrically conductive part of the substrate or to a side of the high voltage semiconductor die that faces away from the substrate, wherein the gate driver semiconductor die comprises a semiconductor body and a polymer material covering a backside of the semiconductor body, wherein the polymer material is interposed between the semiconductor body and the die attach material such that the semiconductor body is electrically insulated from the substrate or the side of the high voltage semiconductor die that faces away from the substrate by an insulator stack that comprises both the polymer material and the die attach material.

Example 2. The semiconductor package of example 1, further comprising: a mold compound encapsulating the high voltage semiconductor die and the gate driver semiconductor die.

Example 3. The semiconductor package of example 1 or 2, wherein the polymer material has a thickness of at least 25 μm.

Example 4. The semiconductor package of example 3, wherein the thickness of the polymer material is in a range of 25 μm to 50 μm.

Example 5. The semiconductor package of any of examples 1 through 4, wherein the polymer material is thicker than the die attach material.

Example 6. The semiconductor package of any of examples 1 through 5, wherein the polymer material has a dielectric strength greater than 25 kV/mm.

Example 7. The semiconductor package of any of examples 1 through 6, wherein the insulator stack has a breakdown voltage greater than 3 kV.

Example 8. The semiconductor package of any of examples 1 through 7, wherein the polymer material is an epoxy or a polyimide.

Example 9. The semiconductor package of any of examples 1 through 8, wherein the die attach material is a die attach film or an epoxy adhesive.

Example 10. The semiconductor package of any of examples 1 through 9, wherein the substrate is a lead frame, wherein both the gate driver semiconductor die and the high voltage semiconductor die are attached to a die paddle a die paddle of the lead frame, and wherein the semiconductor body of the gate driver semiconductor die is electrically insulated from the die paddle by both the polymer material and the die attach material.

Example 11. The semiconductor package of any of examples 1 through 9, wherein the substrate is a lead frame, wherein the high voltage semiconductor die is attached to a die paddle of the lead frame, wherein the gate driver semiconductor die is attached to the side of the high voltage semiconductor die that faces away from the die paddle, and wherein the semiconductor body of the gate driver semiconductor die is electrically insulated from the high voltage semiconductor die by both the polymer material and the die attach material.

Example 12. The semiconductor package of any of examples 1 through 9, wherein the substrate comprises a ceramic body, wherein the electrically conductive part of the substrate is a segment of a patterned metallization formed on the ceramic body, wherein both the gate driver semiconductor die and the high voltage semiconductor die are attached to the segment of the patterned metallization, and wherein the semiconductor body of the gate driver semiconductor die is electrically insulated from the segment of the patterned metallization by both the polymer material and the die attach material.

Example 13. The semiconductor package of any of examples 1 through 9, wherein the substrate is a laminate, wherein the electrically conductive part of the substrate is a segment of a patterned metallization formed on the laminate, wherein both the gate driver semiconductor die and the high voltage semiconductor die are attached to the segment of the patterned metallization, and wherein the semiconductor body of the gate driver semiconductor die is electrically insulated from the segment of the patterned metallization by both the polymer material and the die attach material.

Example 14. The semiconductor package of any of examples 1 through 13, wherein an edge of the gate driver semiconductor die tapers inward.

Example 15. The semiconductor package of any of examples 1 through 14, wherein the high voltage semiconductor die is a microcontroller die for a high voltage transistor or is a discrete high voltage transistor die.

Example 16. The semiconductor package of any of examples 1 through 15, wherein the polymer material comprises a different material than the die attach material.

Example 17. A method of producing a plurality of semiconductor packages, the method comprising: forming a gate driver circuit at a plurality of die locations in a semiconductor wafer; thinning a backside of the semiconductor wafer; covering the thinned backside of the semiconductor wafer with a polymer material; singulating the semiconductor wafer with the polymer material into a plurality of gate driver semiconductor dies; and for each gate driver semiconductor die: attaching a high voltage semiconductor die to an electrically conductive part of a substrate; and attaching, by an electrically insulative die attach material, the gate driver semiconductor die to the electrically conductive part of the substrate or to a side of the high voltage semiconductor die that faces away from the substrate, wherein the polymer material is interposed between a semiconductor body of the gate driver semiconductor die and the die attach material such that the semiconductor body is electrically insulated from the substrate or the side of the high voltage semiconductor die that faces away from the substrate by an insulator stack that comprises both the polymer material and the die attach material.

Example 18. The method of example 17, wherein the singulating comprises: attaching the thinned backside of the semiconductor wafer with the polymer material to a temporary carrier by a die attach film or epoxy adhesive; cutting through the semiconductor wafer along dicing streets which delimit the die locations using a first blade having a first width; and cutting through both the polymer material and the die attach film or epoxy adhesive along the dicing streets using a second blade having a second width that is less than the first width.

Example 19. The method of example 18, wherein the cutting using the first blade tapers inward an edge of each gate driver semiconductor die.

Example 20. The method of example 18 or 19, wherein the die attach film or epoxy adhesive remains on the polymer material of the gate driver semiconductor dies after the singulating and forms the electrically insulative die attach material.

Example 21. The method of any of examples 16 through 20, further comprising: encapsulating each high voltage semiconductor die and corresponding gate driver semiconductor die in a mold compound.

Example 22. The method of any of examples 16 through 21, further comprising: electrically testing the gate driver semiconductor dies before attaching the gate driver semiconductor dies to the electrically conductive part of the corresponding substrate or to the corresponding high voltage semiconductor die.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to mean all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a substrate;
a high voltage semiconductor die attached to an electrically conductive part of the substrate; and
a gate driver semiconductor die attached, by an electrically insulative die attach material, to the electrically conductive part of the substrate or to a side of the high voltage semiconductor die that faces away from the substrate,
wherein the gate driver semiconductor die comprises a semiconductor body and a polymer material covering a backside of the semiconductor body,
wherein the polymer material is interposed between the semiconductor body and the die attach material such that the semiconductor body is electrically insulated from the substrate or the side of the high voltage semiconductor die that faces away from the substrate by an insulator stack that comprises both the polymer material and the die attach material.

2. The semiconductor package of claim 1, further comprising:
a mold compound encapsulating the high voltage semiconductor die and the gate driver semiconductor die.

3. The semiconductor package of claim 1, wherein the polymer material has a thickness of at least 25 μm.

4. The semiconductor package of claim 3, wherein the thickness of the polymer material is in a range of 25 μm to 50 μm.

5. The semiconductor package of claim 1, wherein the polymer material is thicker than the die attach material.

6. The semiconductor package of claim 1, wherein the polymer material has a dielectric strength greater than 25 kV/mm.

7. The semiconductor package of claim 1, wherein the insulator stack has a breakdown voltage greater than 3 kV.

8. The semiconductor package of claim 1, wherein the polymer material is an epoxy or a polyimide.

9. The semiconductor package of claim 1, wherein the die attach material is a die attach film or an epoxy adhesive.

10. The semiconductor package of claim 1, wherein the substrate is a lead frame, wherein both the gate driver semiconductor die and the high voltage semiconductor die are attached to a die paddle of the lead frame, and wherein the semiconductor body of the gate driver semiconductor die is electrically insulated from the die paddle by both the polymer material and the die attach material.

11. The semiconductor package of claim 1, wherein the substrate is a lead frame, wherein the high voltage semiconductor die is attached to a die paddle of the lead frame, wherein the gate driver semiconductor die is attached to the side of the high voltage semiconductor die that faces away from the die paddle, and wherein the semiconductor body of the gate driver semiconductor die is electrically insulated from the high voltage semiconductor die by both the polymer material and the die attach material.

12. The semiconductor package of claim 1, wherein the substrate comprises a ceramic body, wherein the electrically conductive part of the substrate is a segment of a patterned metallization formed on the ceramic body, wherein both the gate driver semiconductor die and the high voltage semiconductor die are attached to the segment of the patterned metallization, and wherein the semiconductor body of the gate driver semiconductor die is electrically insulated from the segment of the patterned metallization by both the polymer material and the die attach material.

13. The semiconductor package of claim 1, wherein the substrate is a laminate, wherein the electrically conductive part of the substrate is a segment of a patterned metallization formed on the laminate, wherein both the gate driver semiconductor die and the high voltage semiconductor die are attached to the segment of the patterned metallization, and wherein the semiconductor body of the gate driver semiconductor die is electrically insulated from the segment of the patterned metallization by both the polymer material and the die attach material.

14. The semiconductor package of claim 1, wherein an edge of the gate driver semiconductor die tapers inward.

15. The semiconductor package of claim 1, wherein the high voltage semiconductor die is a microcontroller die for a high voltage transistor or is a discrete high voltage transistor die.

16. The semiconductor package of claim 1, wherein the polymer material comprises a different material than the die attach material.

17. A method of producing a plurality of semiconductor packages, the method comprising:
forming a gate driver circuit at a plurality of die locations in a semiconductor wafer;
thinning a backside of the semiconductor wafer;
covering the thinned backside of the semiconductor wafer with a polymer material;
singulating the semiconductor wafer with the polymer material into a plurality of gate driver semiconductor dies; and
for each gate driver semiconductor die:
attaching a high voltage semiconductor die to an electrically conductive part of a substrate; and
attaching, by an electrically insulative die attach material, the gate driver semiconductor die to the electrically conductive part of the substrate or to a side of the high voltage semiconductor die that faces away from the substrate,
wherein the polymer material is interposed between a semiconductor body of the gate driver semiconductor die and the die attach material such that the semiconductor body is electrically insulated from the substrate or the side of the high voltage semiconductor die that faces away from the substrate by an insulator stack that comprises both the polymer material and the die attach material.

18. The method of claim 17, wherein the singulating comprises:
attaching the thinned backside of the semiconductor wafer with the polymer material to a temporary carrier by a die attach film or epoxy adhesive;
cutting through the semiconductor wafer along dicing streets which delimit the die locations using a first blade having a first width; and
cutting through both the polymer material and the die attach film or epoxy adhesive along the dicing streets using a second blade having a second width that is less than the first width.

19. The method of claim 18, wherein the cutting using the first blade tapers inward an edge of each gate driver semiconductor die.

20. The method of claim 18, wherein the die attach film or epoxy adhesive remains on the polymer material of the gate driver semiconductor dies after the singulating and forms the electrically insulative die attach material.
